(19) United States
(12) Patent Application Publication
(10) Pub. No.: US 2018/0287333 A1
(43) Pub. Date: Oct. 4, 2018

(54) An Apparatus Comprising A Waveguide-Modulator And Laser-Diode And A Method Of Manufacture Thereof

(71) Applicants: KING ABDULLAH UNIVERSITY OF SCIENCE AND TECHNOLOGY, Thuwal (SA); KING ABDULAZIZ CITY FOR SCIENCE AND TECHNOLOGY, RIYADH (SA)

(72) Inventors: Boon Siew Ooi, Thuwal (SA); Chao Shen, Thuwal (SA); Tien Khee Ng, Thuwal (SA); Ahmed Alyamani, Riyadh (SA); Munir Eldesouki, Riyadh (SA)

(21) Appl. No.: 15/766,188

(22) PCT Filed: Oct. 5, 2016
(86) PCT No.: PCT/IB2016/055967

§ 371 Date: Apr. 5, 2018

Related U.S. Application Data
(60) Provisional application No. 62/237,523, filed on Oct. 5, 2015.

(51) Int. Cl. H01S 5/026; H01S 5/32; H01S 5/343; H01S 5/0683; H01S 5/22

(52) U.S. Cl. CPC H01S 5/0265; H01S 5/0264; H01S 5/22; H01S 5/34333; H01S 5/0683; H01S 5/3202

(57) ABSTRACT

Example apparatuses are provided for simultaneous generation of high intensity light and modulated light signals at low modulation bias operating characteristics. An example apparatus includes a semipolar or nonpolar GaN-based substrate, a reverse-biased waveguide modulator section, and a forward-biased gain section based on InGaN/GaN quantum-well active regions, wherein the forward-biased gain section is grown on the semipolar or nonpolar GaN-based substrate. Methods of manufacturing the apparatuses described herein are also contemplated and described herein.

### TECHNOLOGICAL FIELD

Example embodiments of the present invention relate generally to light amplification by stimulated emission of radiation (laser) and, more particularly, to methods and apparatuses for monolithic integration of optical modulators with laser diodes.

### BACKGROUND

To date, solid-state lighting (SSL), visible light communication (VLC) and optical clock generation functionalities in group-III-nitrides, especially those operating in the blue-green color regime, have required the use of multiple discrete components. These components include light-emitting diodes, laser diodes, and transverse-transmission modulators. However, because these components are packaged as discrete components, they suffer from suboptimal characteristics. In this regard, existing arrangements focus on: (a) devices based on a GaAs or InP substrate operating at near-infrared wavelengths; (b) discrete nitride-based components; or (c) devices grown on c-plane sapphire substrate having a large-modulation bias voltage.

The technologies in category (a), which are based on electroabsorption modulators and their integration with laser diodes, were mainly reported for GaAs—AlGaAs, InP-AlGalnAs and InP-GalnAsP material systems. Because these technologies enable the modulation of a laser beam in the infrared wavelength range, they do not work for a blue-green color regime (e.g., wavelengths from 400 nm˜550 nm), or the ultraviolet/visible/far-red spectrum in general.

Using technologies in category (b), transverse-transmission modulators in the visible range have been demonstrated that are based on group-III-nitride materials, including InGaN or GaN quantum wells (QWs) or GaN bulk film. The InGaN or GaN QWs have consisted of blue quantum electroabsorption modulators grown on c-plane sapphire for operation between 420 and 430 nm. Owing to the high polarization field in InGaN/GaN QWs on c-plane sapphire substrate, such modulators have shown a reversed quantum confined Stark effect in conjunction with energy blueshift. While electroabsorption modulators based on bulk GaN films provide similar performance levels as the quantum well devices, this fact is mainly a consequence of the uniquely large exciton binding energies of nitride semiconductors. However, the published studies all focus on the discrete components and do not provide solution to enable SSL and VLC applications.

As for category (c), U.S. Pat. No. 6,526,083 (the '083 patent) describes a group-III nitride multi-mode blue laser diode having an amplifier region and a modulator region grown on a c-sapphire substrate. However, the technology described in the '083 patent is targeted at reducing output power droop, and not as a light-base transceiver device. If the device were implemented as a signal transmitter, a high bias voltage—and thus a high power consumption—would be expected due to the large polarization field in the device grown on the conventional c-plane sapphire substrate.

The monolithic integration of optoelectronic and photonic components at the chip-level is thus desirable to achieve the economic benefits of small-footprint, high-speed, and low-power consumption devices.

### BRIEF SUMMARY

Example embodiments contemplated herein comprise a two-section device adjoining an integrated waveguide-modulator and a laser-diode (IWM-LD) operating at low modulation bias and in the blue-green color regime (and in some embodiments, at the visible wavelength of 448 nm). As described below, example embodiments are manufactured by growing the devices on a non-c-plane GaN substrate, such as, but not limited to, semipolar or non-polar group-III nitride quantum structures. The resulting epitaxial structure is co-shared by the low or zero polarization field passive waveguide modulator and single mode Fabry-Perot active region (the lasing region). The light modulation (at the modulator section) is achieved by externally cancelling and/or inducing the quantum-confined Stark effect (QCSE) using a considerably small bias voltage. By co-sharing the same layer structure, the fabrication process is greatly simplified and forgoes a complicated epitaxy regrowth process. The GaN—InGaN material system provides light emission and modulation at, but not limited to, the violet-blue-green color regime, which is a desired wavelength range for solid state lighting, visible light communication, and laser-based horticulture.

In a first example embodiment, an IWM-LD apparatus is provided. The apparatus is a three-terminal device consisting of a reverse-biased waveguide modulator section and a forward-biased gain section. These sections may be disposed on a semipolar or nonpolar GaN-based substrate. Moreover, the forward-biased gain section may utilize InGaN/GaN quantum-well active regions and may be grown on the semipolar or nonpolar GaN-based substrate. In some embodiments, the semipolar or nonpolar GaN-based substrate comprises a bulk GaN substrate or a group-III-nitride-based template-substrate. In this regard, the template substrate may include planar, micro-structured crystals or nano-structured crystals of GaN fabricated on silicon, sapphire, silicon carbide, AlN, or InN substrates.

In some embodiments, the reverse-biased waveguide modulator section of the apparatus may include a monitoring photodetector section configured to enable power monitoring and auto-tuning. In other embodiments, the monitoring photodetector section may be a separate section of the apparatus from the reverse-biased waveguide modulator section.

In some embodiments, the reverse-biased waveguide modulator section of the apparatus may include a forward-biased semiconductor optical amplifier section. In other embodiments, however, the forward-biased semiconductor optical amplifier section may be a separate section of the apparatus from the reverse-biased waveguide modulator section.

In some embodiments, the reverse-biased waveguide modulator section of the apparatus may include a semiconductor saturable absorber section configured to enable pulse generation or optical clocking. In other embodiments, however, the semiconductor saturable absorber section may be a separate section of the apparatus from the reverse-biased waveguide modulator section.

The forward-biased gain section may, in some embodiments, comprise a superluminescent diode or light-emitting diodes for generating speckle-free light. Additionally or alternatively, the apparatus may be configured to emit light having a wavelength between 440 and 470 nm.

The apparatus may be utilized in a variety of environments. For instance, a communication system may be configured to enable high rate data transmission in the gigabit (Gbit) per second range for applications including, but not limited to free-space, fiber-based and under-water visible light communication. Such communication systems may utilize example embodiments of the apparatus as a high-speed and low-power-consumption transmitter. As another example, an SSL-VLC multiple function lamp may be provided for smart lighting. The SSL-VLC multiple function lamp may utilize example embodiments of the apparatus for similar reasons. In other examples, embodiments of the apparatus described herein may be used for high speed direct modulation of laser diodes, low power consumption laser based visible light communication, as a dense wavelength-division multiplexing transmitter in the visible spectral range, as a high efficiency orthogonal frequency-division multiplexing (OFDM) transmitter for data transmission, or for integrated power monitoring in laser diodes.

In a second example embodiment, a method of fabricating a multi-section group-III nitride semiconductor apparatus is provided. The method includes growing an InGaN laser diode epitaxial structure in a semipolar or nonpolar GaN-based substrate. In this regard, the epitaxial structure includes one or more of an Si-doped n-GaN template, an Si-doped n-InGaN separate confinement heterostructure (SCH), a waveguiding layer, an undoped multiple quantum well (MQW) active region with InGaN quantum wells (QWs) and GaN barriers, a doped p-AlGaN electron blocking layer (EBL), a low Mg-doped p-InGaN SCH waveguiding layer, a standard Mg-doped p-GaN cladding layer, or a highly Mg-doped p-GaN contact layer.

In some embodiments, the fabrication method includes defining a ridge waveguide multi-section laser diode using ultraviolet (UV) photolithography and inductively coupled plasma (ICP) etching. In some embodiments, the method may further include etching, into an InGaN cladding layer, an isolation trench between an IM region and a gain region. In this regard, the method may include removing a metal contact layer and a highly doped GaN layer to provide electrical isolation and maintain optical coupling.

In some embodiments, the fabrication method includes dry-etching facets along an a-direction without dielectric coating. Additionally or alternatively the fabrication method may include depositing Pd/Au and Ti/Al/Ti/Au metallization layers using sputter as p- and n-electrodes, respectively. As yet another additional or alternative step, the fabrication method may include selecting an In concentration and thickness of an InGaN well that enables a production of wavelengths of light in the ultraviolet, visible, or near-infrared regime.

The above summary is provided merely for purposes of summarizing some example embodiments to provide a basic understanding of some aspects of the invention. Accordingly, it will be appreciated that the above-described embodiments are merely examples and should not be construed to narrow the scope or spirit of the invention in any way. It will be appreciated that the scope of the invention encompasses many potential embodiments in addition to those here summarized, some of which will be further described below.

### BRIEF DESCRIPTION OF THE DRAWINGS

Having thus described certain example embodiments of the present disclosure in general terms, reference will now be made to the accompanying drawings, which are not necessarily drawn to scale.

FIG. 1 illustrates a schematic drawing of an example integrated waveguide modulator-laser diode fabricated on a semipolar GaN substrate, in accordance with example embodiments described herein.

FIG. 2 provides a graph illustrating a lasing spectrum of the example integrated waveguide modulator-laser diode illustrated in FIG. 1, in accordance with example embodiments described herein.

FIG. 3 illustrates a scanning electron microscope (SEM) top-view of the example integrated waveguide modulator-laser diode illustrated in FIG. 1, in accordance with example embodiments described herein.

FIG. 4 provides a graph illustrating output power vs. injection current (L-I) relations of the example integrated waveguide modulator-laser diode illustrated in FIG. 1 with varying bias voltage applied to the IM section. The light output power at I_{LD}=500 mA is indicated.

FIG. 5 provides a graph illustrating the light output power of the example integrated waveguide modulator-laser diode illustrated in FIG. 1 at an injection of 500 mA in the gain region (Pout-500 mA) as a function of the applied modulation bias in the IM section (V_{IM}). The insets in FIG. 4 comprise photographs of the example integrated waveguide modulator-laser diode illustrated in FIG. 1 operating in on and off states, in accordance with example embodiments described herein.

FIG. 6 provides a graph illustrating the change in absorption versus wavelength in semipolar (202̅1̅) InGaN/GaN QWs under applied reverse bias (V_{IM}) from −1 V to −6 V with respect to the absorption at zero bias.

FIG. 7 provides a graph illustrating a simulated band diagram of semipolar (202̅1̅) InGaN/GaN QWs showing downward band-bending, in accordance with example embodiments described herein. The directions of piezoelectric field (E_{piezo}), modulation bias-induced field (E_{applied}), and the combination of fields (E_{piezo}+E_{applied}) are labelled.

FIG. 8 provides a graph illustrating a simulated band diagram of semipolar (202̅1̅) InGaN/GaN QWs showing flat-band under reverse bias of −1 V, in accordance with example embodiments described herein. The directions of piezoelectric field (E_{piezo}), modulation bias-induced field (E_{applied}), and the combination of fields (E_{piezo}+E_{applied}) are labelled.

FIG. 9 provides a graph illustrating a simulated band diagram of semipolar (202̅1̅) InGaN/GaN QWs showing upward band-bending at −4 V, in accordance with example embodiments described herein. The directions of piezoelectric field (E_{piezo}), modulation bias-induced field (E_{applied}), and the combination of fields (E_{piezo}+E_{applied}) are labelled.

FIGS. 10 and 11 provides graphs illustrating the external field-dependent optical absorption response in semipolar (202̅1̅) InGaN/GaN QWs as compared to that of c-plane InGaN/GaN QWs with a similar transition energy, respectively.

FIG. 12 provides a graph illustrating the small signal modulation response of the example integrated waveguide modulator-laser diode illustrated in FIG. 1 under injection current of 500 mA and IM bias of −3.5 V, showing a −3 dB bandwidth of −1 GHz. The inset eye-diagram illustrates the 1 Gbit/s data rate based on OOK modulation on the example integrated waveguide modulator-laser diode.

FIG. 13 illustrates another schematic diagram of an integrated electroabsorption-modulator-laser (IML) on semipolar (202̅1̅) GaN substrate, in accordance with some example embodiments described herein.

FIG. 14 provides a graph plotting optical power vs injection current of the IML described in FIG. 13 using varying bias voltages. The optical power at 468 (1.2 Iₜₕ) in the gain region is indicated.

FIG. 15 provides a graph plotting optical power at 468 mA against the absolute modulation bias voltage, |V_{IM}| for the IML described in FIG. 13.

FIG. 16 provides a graph illustrating modal absorption spectra under different modulation bias voltages (V_{IM}) for the IML described in FIG. 13.

FIG. 17 provides a graph illustrating small signal modulation of IML described in FIG. 13 under injection current of 470 mA and modulation bias voltage of −3V.

### DETAILED DESCRIPTION

Some embodiments of the present invention will now be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements.

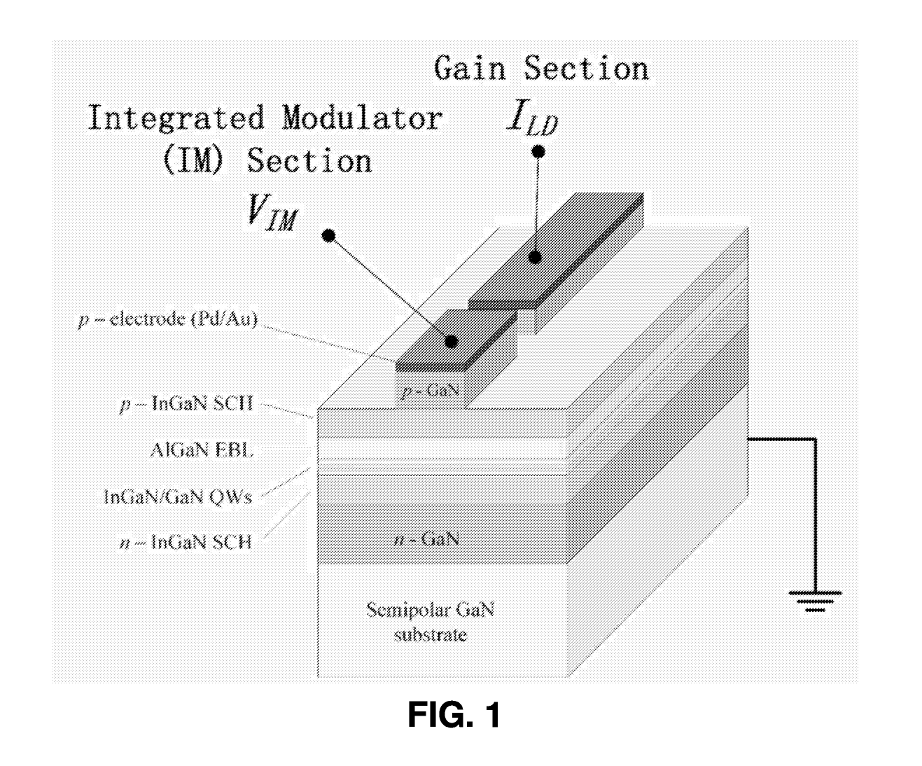

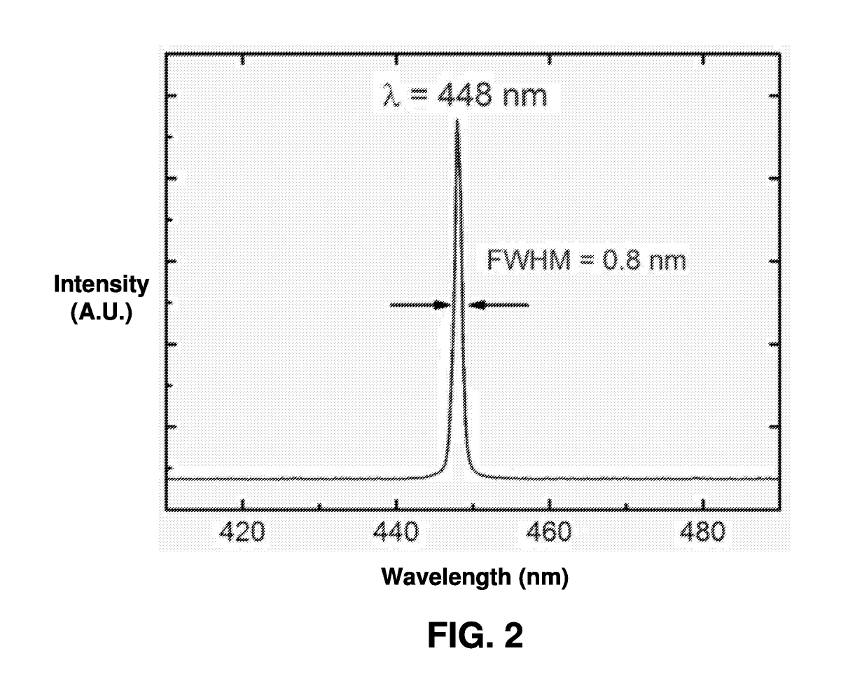

As noted above, example embodiments contemplated herein comprise an IWM-LD two-section device, such as that shown in FIG. 1. Moreover, some example embodiments are configured to operate at a low modulation bias and at the visible wavelength of 448 nm, as shown in FIG. 2. Example embodiments are manufactured by growing the devices on a non-c-plane GaN substrate, such as, but not limited to, a semipolar or non-polar group-III nitride quantum structure. The resulting epitaxial structure may then be co-shared by a low or zero polarization field passive waveguide modulator (the modulator section) and a single mode Fabry-Perot active region (the lasing region). The light modulation (at the modulator section) may be achieved by externally cancelling and/or inducing the quantum-confined Stark effect (QCSE) using a small bias voltage (relative to traditional mechanisms for light modulation). By co-sharing the same layer structure, the fabrication process is greatly simplified and forgoes a complicated epitaxy regrowth process. The GaN—InGaN material system provides light emission and modulation at, but not limited to, the violet-blue-green color regime, which is a desired wavelength range for solid state lighting (SSL), visible light communication (VLC), and laser-based horticulture.

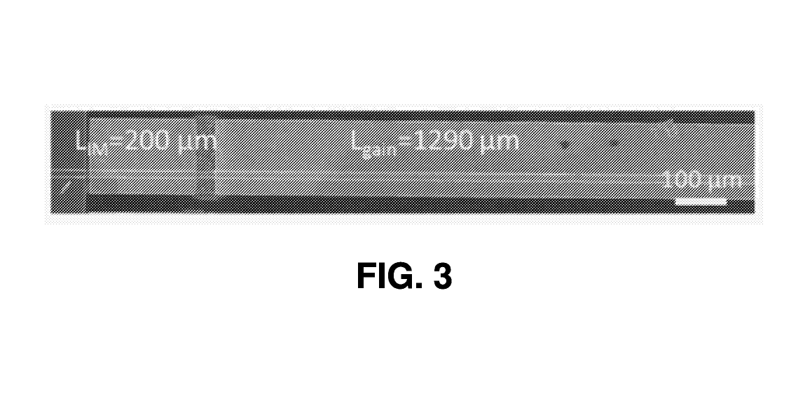

In some embodiments contemplated herein, the IWM-LD is a three-terminal device consisting of a reverse-biased waveguide modulator section and a forward-biased gain section. One example implementation of an IWM-LD device is described herein, although it should be understood that other implementations may be manufactured in alternative embodiments. In the example implementation described herein, the IWM-LD device is made of a 2-μm-wide ridge-waveguide, where a narrow (e.g., a full width at half maximum (FWHM) of 0.8 nm) single mode emission with a peak wavelength at 448 nm is produced, as shown in FIG. 2. A fabricated device as contemplated in this embodiment consists of a 200-μm-long integrated modulator (IM) section and a 1.29 mm long gain (lasing) section. A SEM top-view of this example IWM-LD is shown in FIG. 3. Both sections share the same quantum-well active region layer-structure and are optically coupled in a seamless manner, allowing the emitted beam from the gain section to be modulated by the IM section. The epitaxial layers can be grown using metal-organic chemical-vapor deposition (MOCVD). Owing to the high lateral resistance of the InGaN waveguiding layer and the AlGaN electron blocking layer (EBL), the IM section and gain section may in some embodiments be electrically separated, enabling the independent operation of these two sections. The isolation resistance between the two sections may be 1.2 MO, which is 5 orders of magnitude higher than the series resistance for the laser diode (LD).

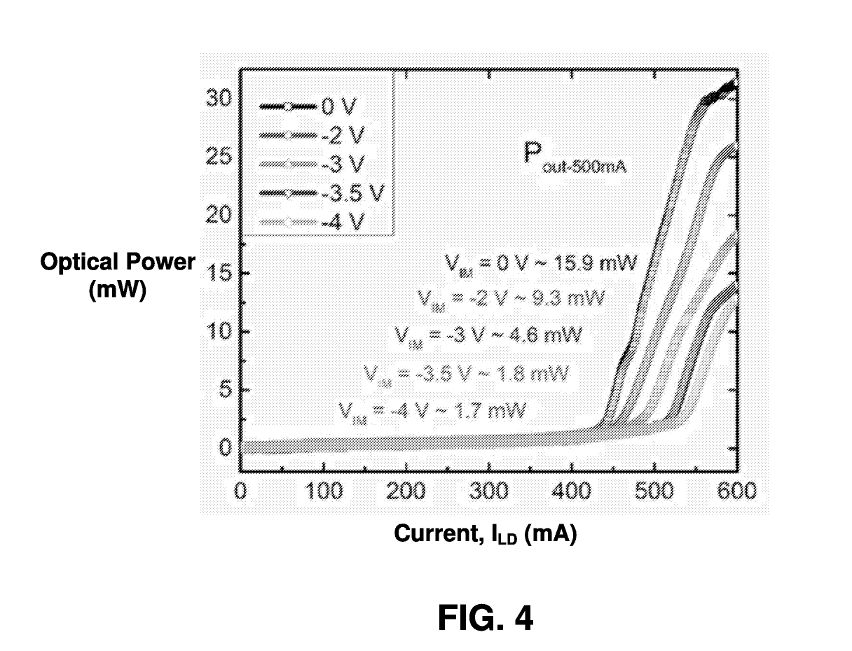

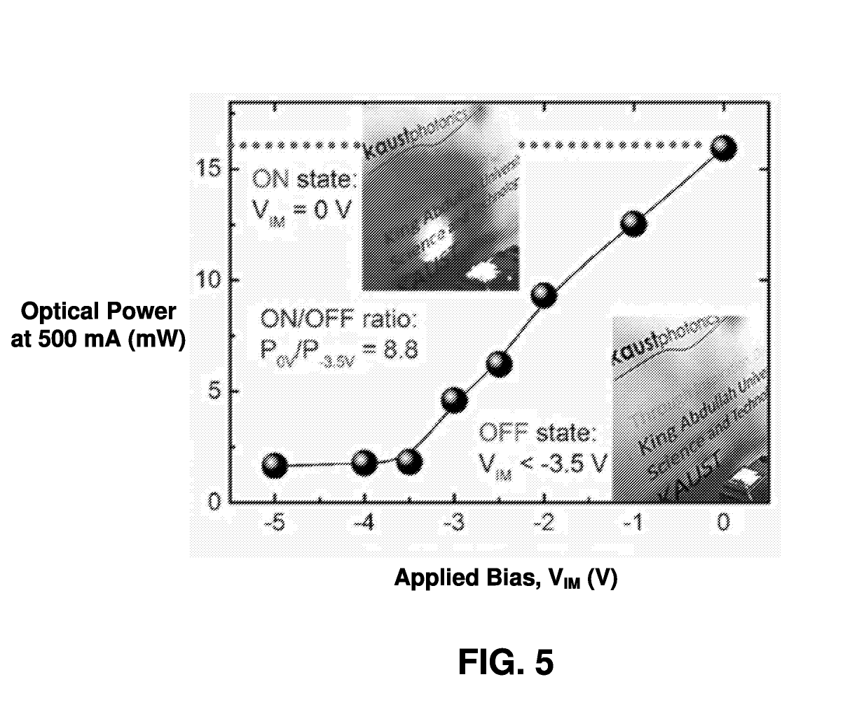

FIG. 4 shows the optical output power (L) vs. injection current in the IWM-LD gain region (ILD) with various reverse biases applied to the waveguide modulator (VIM from 0 V to −4 V). Without any modulation bias (V_{IM}=0 V), an IWM-LD having the above dimensions and characteristics has a threshold current (Iₜₕ) of 435 mA. Further increases in injection current to 500 mA at the gain section (I_{LD}=1.15 Iₜₕ) in turn result in an optical output power of 15.9 mW under DC operation. An example IWM-LD having these dimensions and characteristics was limited to 600 mA as the thermal roll-over became significant when I_{LD}>600 mA. With increasing |V_{IM}| applied to the IM region, decreasing optical power and increasing lasing threshold current were observed in the IWM-LD device due to increasing loss. For example, the optical power of the IWM-LD at I_{LD}=500 mA was reduced to 9.3, 4.6, and 1.8 mW at V_{IM}=−2, −3, and −3.5 V, respectively. The strong V_{IM}-dependence in optical power is evident in FIG. 5, which illustrates the light output power of the example integrated waveguide modulator-laser diode IWM-LD at an injection of 500 mA in the gain section (Pout-500 mA) as a function of the applied modulation bias in the IM section (V_{IM}) indicating the amplitude modulation effect. The modulation bias applied to the IM section controls the light output by switching the absorption from a low value to a high value. With a constant driving current (I_{LD}) of 500 mA in the gain section, the lasing was suppressed at V_{IM}=−3.5 V, which represented the Off state. The IWM-LD has its maximum emission power at V_{IM}=0 V, which is the On state. At I_{LD}=500 mA, the IWM-LD exhibited a high extinction ratio (R_{on/off}=P_{ON}/P_{OFF}) of 8.8 (9.4 dB) with a relatively small bias of 0/−3.5 V. In turn, the example implementation shows a high modulation efficiency of 2.68 dB/V. The modulation effect results from the external field-induced quantum-confined-Stark-effect (QCSE). The IWM-LD based on a semipolar (202̅1̅) QWs is able to operate similarly to other III-V materials typically used in optical telecommunications due to the reduced piezoelectric field. One of the critical advantages of the IWM-LD implementation on the same semipolar QW epitaxy is enabling a high-efficiency platform toward SSL-VLC functionalities.

In some embodiments, IWM-LD emits light beam in blue (440-470 nm) regime and this emission can be efficiently detected using Si based photodetectors (PDs), unlike conventional GaAs and InP-based near-infrared (NIR) devices, which have a long absorption length in silicon. In turn, unlike conventional devices, these embodiments of the IWM-LD are therefore compatible with CMOS-based Si PDs. Thus, the IWM-LD may also be used with Si or SiGe PDs in the implementation of high-speed optical interconnects (OIs) and photonic integrated circuits (PICs), or any other III-V-silicon integration technologies.

Example embodiments of the IWM-LD described herein provide high brightness light emission and modulated light signals, including not limited to the ultra-violet—visible color regime, and thus can be widely used as a compact, efficient and cost-effective light source or the like. As a result, blue-color emitting IWM-LDs, when integrated with a yellow-emitting phosphor or green and red phosphors, are useful for generating white light emission for various illumination applications, including but not limited to the indoor lighting, small foot-print projector and high power display.

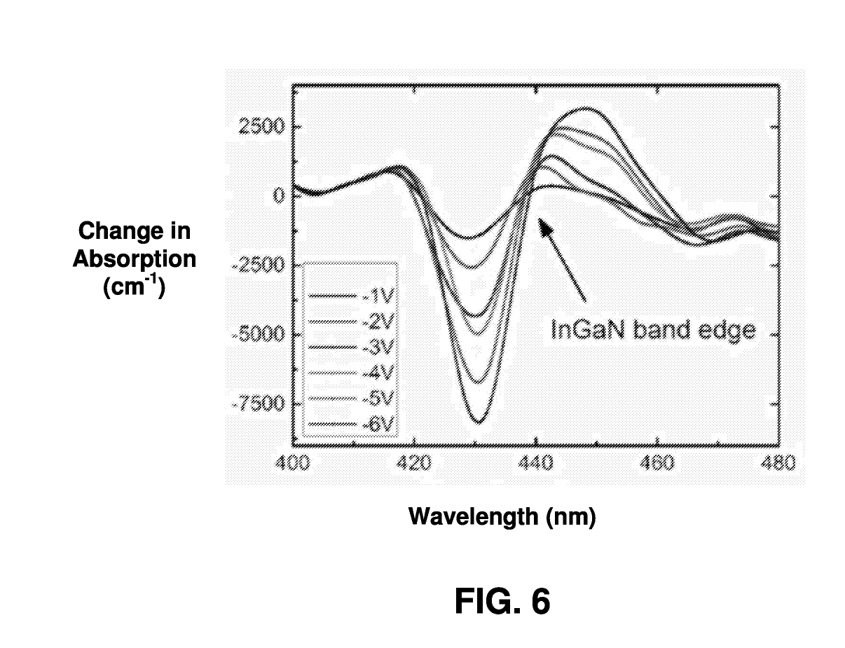

Turning next to FIG. 6, the changes in absorption (La) of semipolar InGaN/GaN QWs were obtained from the electrotransmission measurements with different modulation bias voltages applied to the QW. The spectra of absorption changes shown in FIG. 6 were derived based on the transmission spectrum at zero modulation bias, according to the relationship:

$$Δα = \frac{1}{d} ln ( \frac{{P}_{{V}_{IM}}}{{P}_{0 V}} ) ,$$

where d is the total thickness of the InGaN QW layers. P_{V}_{_{IM}} refers to the transmitted optical power when modulation bias is applied to the device and P_{0V} refers to the transmitted optical power at zero modulation bias. The external field-induced absorption changes occur for photon energies near the transition energy of QWs within the space charge region of the p-i-n junction. Because the active layer for our device consists of InGaN QWs embedded within GaN barriers, the EA signature for the InGaN layers, with a total thickness (d) of 14.4 nm, can be observed separately at 448 nm. The absorption of the InGaN QWs can be strongly modulated around the lasing wavelength by the applied external field. With increasing modulation bias |V_{IM}| from −1 V to −6 V, a broadening and redshift of the absorption edge can be identified in a semipolar (202̅1̅) InGaN/GaN waveguide modulator. This trend, in which the increasing modulation bias leads to a growing internal field within the entire space charge region, is similar to the behavior of AlGaAs/GaAs-based heterostructures, which do not present an internal piezoelectric field. With increasing the peak |V_{IM}|, the absorption change spectrum shifts from 441 nm (V_{IM}=−1 V) to 446 nm (V_{IM}=−6 V) and the absorption change at the lasing wavelength (A=448 nm) increases from 200 cm⁻¹ (V_{IM}=−1 V) to 3200 cm⁻¹ (V_{IM}=−6 V). The monotonic increase in the absorption change and red-shifting of the absorption edge are attributed to the external field-induced quantum-confined-Stark-effect (QCSE), which is utilized to modulate the absorption in IWM-LDs, as shown in FIGS. 4 and 5.

In c-plane InGaN/GaN QWs, there exists a strong piezoelectric field (approximately 3.1 MV/cm in an In0.2Ga0.8N layer) due to the large total polarization discontinuity (as high as 0.03 C/m2 in an In0.2Ga0.8N layer). Moreover, the directions of the piezoelectric field and the p-n junction built-in field in c-plane InGaN/GaN QWs are opposite. As a result, when a reverse modulation bias is applied to the QW grown on c-plane GaN, it will compensate the piezoelectric field in the InGaN QWs before introducing a net electric field in the direction of the built-in field of the QWs.

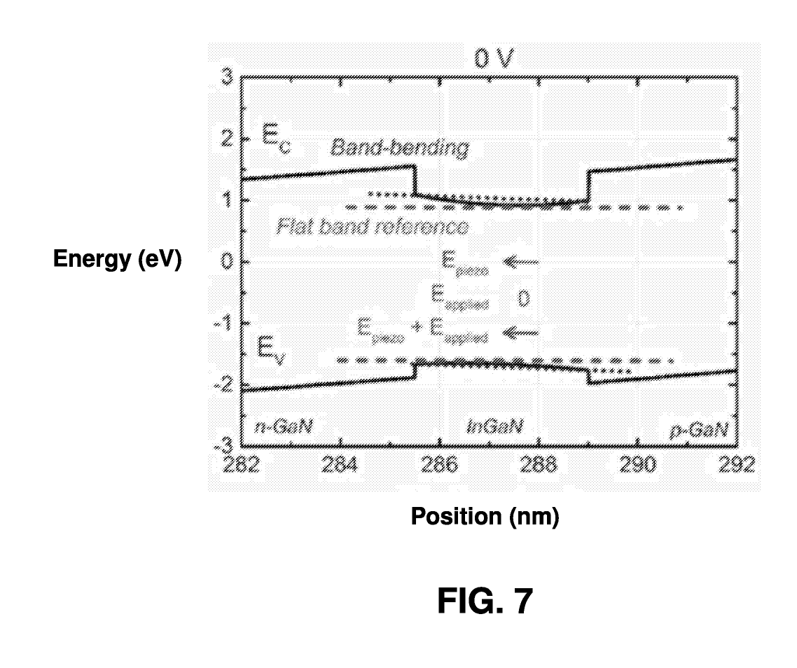

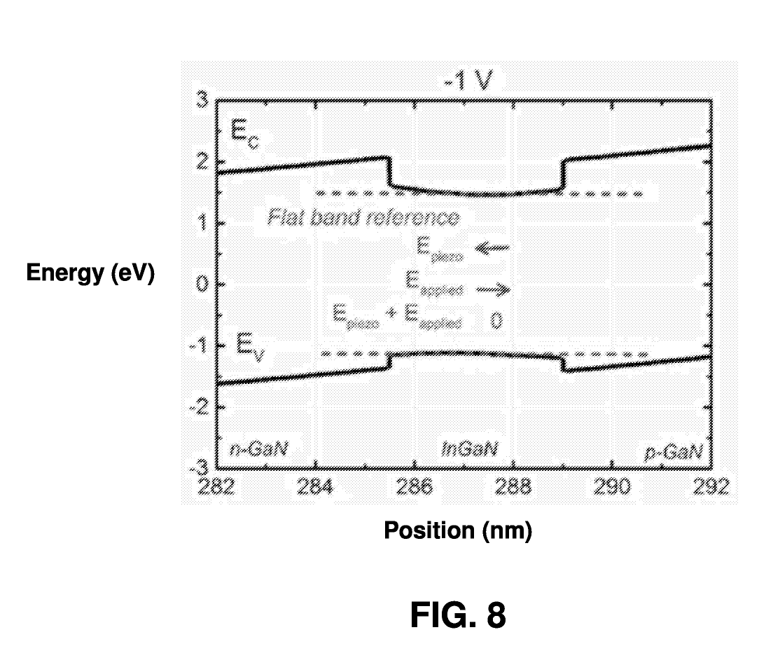

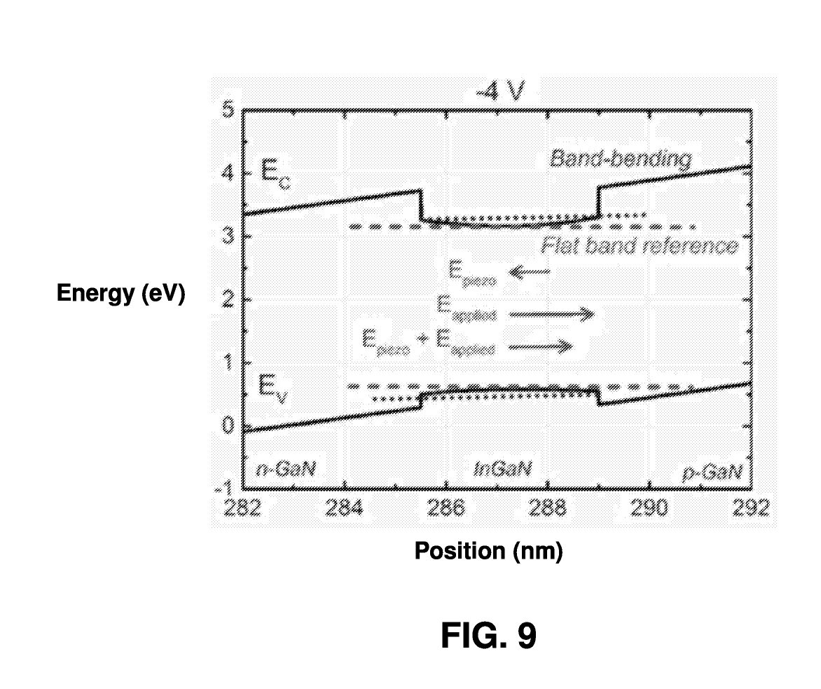

Therefore, the applied modulation bias will first reverse the piezoelectric field-induced QCSE effect, leading to a blue-shifting and narrowing of the absorption edge. Only when the applied modulation bias-induced external field exceeds the piezoelectric field can the effect of broadening and red-shifting of the absorption edge be achieved. For typical c-plane InGaN-based QWs, an additional bias voltage of larger than 10 V is required to create an external field to compensate for the piezoelectric field. The modulation voltage required for the semipolar (202̅1̅) InGaN/GaN QW-based IWM-LD is, however, considerably smaller due to the significantly reduced piezoelectric field compared to the QWs grown on a polar c-plane. To further the understanding of external-field induced effects, we performed simulation study to investigate the band-bending in semipolar (202̅1̅) InGaN/GaN QWs using SiLENSe (software for simulation of light emitting heterostructures). FIG. 7 shows the band diagram in equilibrium, where a band-bending can be identified owing to the piezoelectric field (E_{piezo}). When a negative bias is applied, the modulation bias induced field (E_{applied}) will first compensate the piezoelectric field to reach the flat-band condition (E_{piezo}+E_{applied}=0). In semipolar (202̅1̅) InGaN/GaN QWs, a flat-band is observed in the band diagram of the QWs under reverse biases of −1 V, as shown in FIG. 8, indicating a much smaller external field required to compensate E_{piezo}. With increasing reverse bias to −4 V, E_{applied} exceeds E_{piezo}, resulting in a band-bending of the opposite direction to the equilibrium condition, which is identified in the band diagram of the QWs shown in FIG. 9. As a result, the introduction of external field-induced QCSE leads to a major change in absorption at the lasing wavelength, which can be as large as 1800 cm⁻¹ with a small modulation bias of −4 V according to the measurement shown in FIG. 6. The theoretical modeling confirms the fact that a considerably small modulation voltage is expected in blue-green emitting IWM-LDs based on semipolar InGaN/GaN QWs, leading to high modulation efficiency and low power consumption.

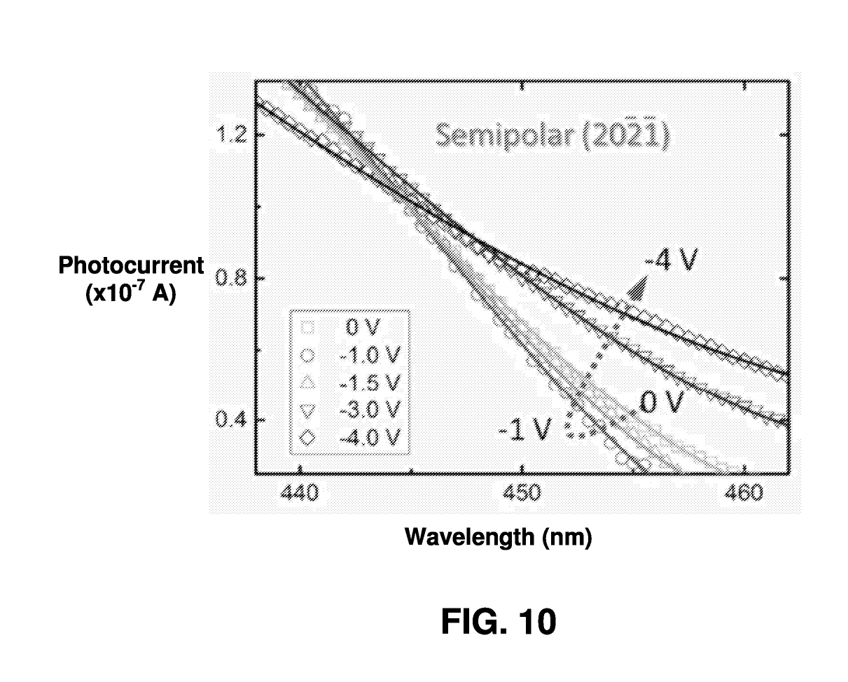

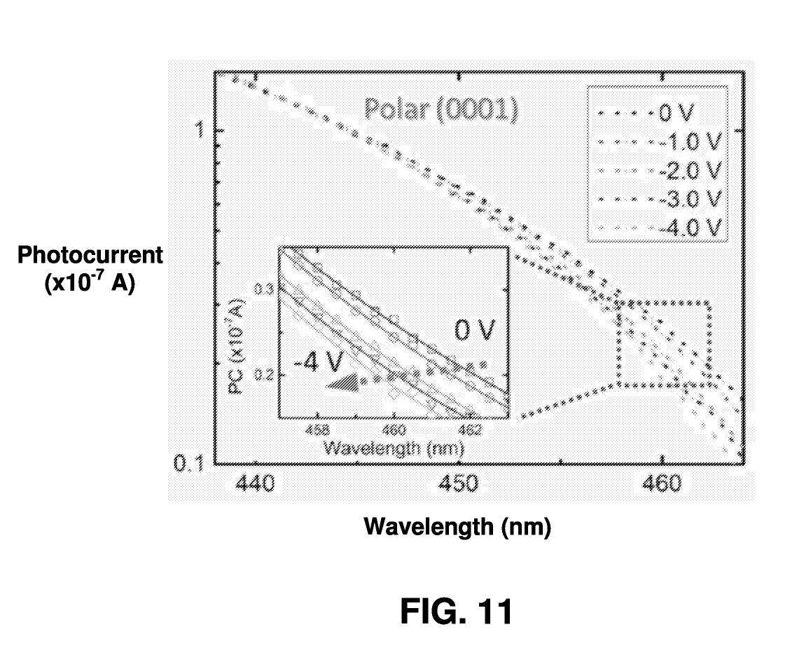

FIGS. 10 and 11 further provides photocurrent measurements to illustrate the external field-dependent optical absorption response in semipolar (202̅1̅) InGaN/GaN QWs as compared to that of c-plane InGaN/GaN QWs with a similar transition energy. FIG. 10 illustrates the photocurrent spectrum collected around the absorption edge of the example IWM-ID at room temperature. For comparison purposes, FIG. 11 illustrates the photocurrent spectrum from c-plane InGaN/GaN QWs with a similar transition energy. As might be expected, the polar QW exhibits a monotonic blue-shifting absorption edge with an increasing applied electric field due to the reversed QCSE with V_{IM} from 0 V to −4 V. With regard to the semipolar QW, similar blue-shifting was observed when a small negative bias was applied (0 V to −1 V). Interestingly, the absorption edge of the semipolar QW shows a red-shifting trend when an increasing negative bias (>2 V) is applied. The red-shifting clearly indicates the occurrence of a QCSE-induced redshift in the absorption edge. The change is due to the applied external field on the IM canceling the built-in polarization-induced electric fields in the active region and thus manifesting itself as in conventional GaAs-based materials. Due to a reduced piezoelectric field in semipolar QWs, the significant shifting of absorption edges in the IM region in response to modulation bias is effective in modulating the optical output power of the IWM-LD.

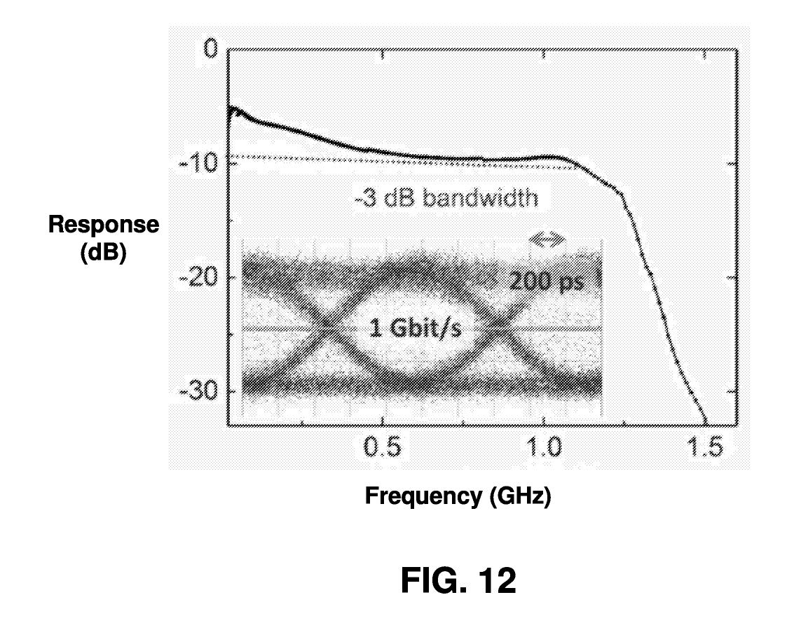

A proof-of-concept demonstration of AC modulation using the example IWM-LD scheme described above was made via a small-signal modulation measurement applying a −10 dBm AC signal to the integrated modulator while pumping the gain region with a constant driving current (500 mA). FIG. 12 illustrates the frequency response of the tested IWM-LD, in which a −3 dB bandwidth of approximately 1 GHz was measured with |V_{IM}|=3.5 V. The maximum bandwidth of the example IWM-LD described above is expected to exceed 1 GHz due to the 1 GHz bandwidth limitation of the photodetector used in the measurement setup. Subsequently, a pseudorandom binary sequence (PRBS 2¹⁰−1) NRZ-OOK data stream was used to modulate the IWM-LD and the eye diagram showing a data rate at 1 Gbit/s can be found in the inset of FIG. 12. The open eye observed from the figure confirms the potential of utilizing integrated waveguide modulator for high-speed VLC applications. Higher data rates could be achieved by further optimization of the system and employing complex modulation schemes, such as OFDM. Nevertheless, this demonstration proves the feasibility of using this example IWM-LD for data transmission.

Accordingly, the above description demonstrates the monolithic integration of an electroabsorption waveguide modulator with a laser diode and illustrates the DC and AC modulation characteristics of an example device grown on a (202̅1̅) plane GaN substrate. By alternating the modulation voltages at −3.5 V and 0 V, the laser output power can be tuned from 1.8 to 15.9 mW, respectively, leading to an On/Off ratio of 9.4 dB. These results clearly demonstrate that modulation can be achieved using a semipolar EA-modulator that consumes less power compared to c-plane devices. Moreover, this description illustrates the physical mechanism of QCSE-induced absorption change, leading to the promising deployment of the blue-green-red electromagnetic spectrum for utilization in compact SSL-VLC devices. Moreover, this illustration is further beneficial for III-V-Si integration, by combining III-N lasers and CMOS-based Si photodetectors (PDs). Thus, based on the above description, example GaN-based IWM-LDs may further be implemented in high-speed optical interconnects (OIs) and photonic integrated circuits (PICs).

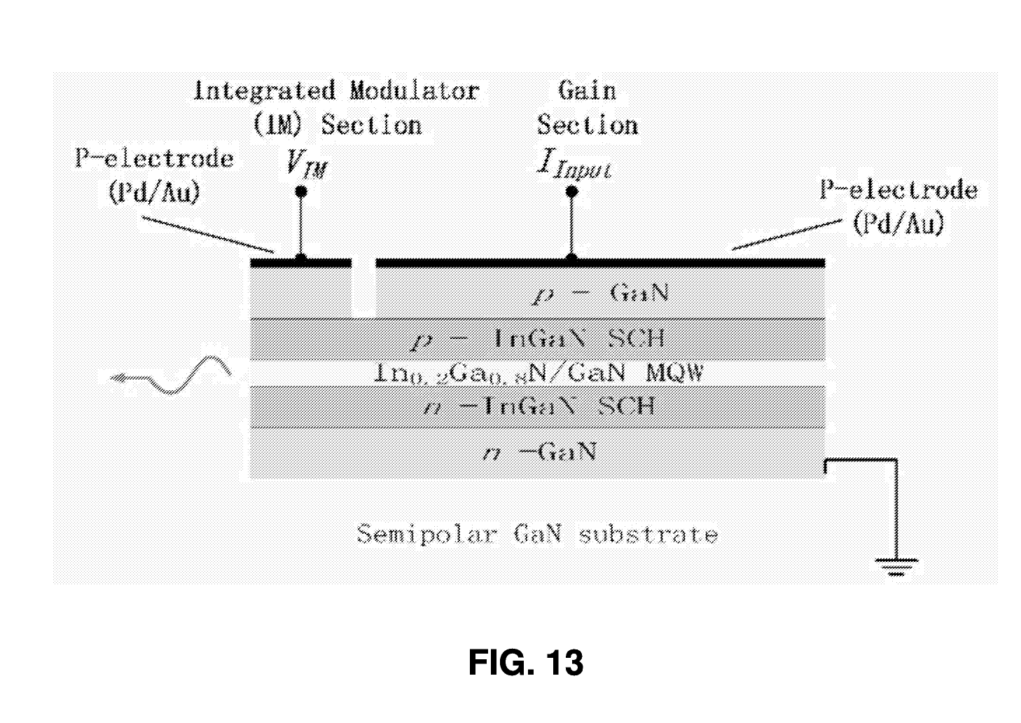

Turning next to FIG. 13, another illustration of an example IWM-LD is provided. This example InGaN/GaN QW based IML is a three-terminal device consisted of reverse-biased integrated modulator section and forward-biased gain section grown using metalorganic chemical vapor deposition (MOCVD). The IML is made of 2 μm-wide ridge waveguide with 100 μm integrated modulator (IM) and 1100 μm gain sections. Both sections are optically coupled but electrically separated (22 kΩ resistance between the two sections). The device was tested using Keithley 2520 diode laser testing system with calibrated Si photodetector and integrating sphere from Labsphere. The small signal modulation characteristics were measured using Agilent E8361C network analyzer and Menlo Systems APD 210 Si avalanche photodetector.

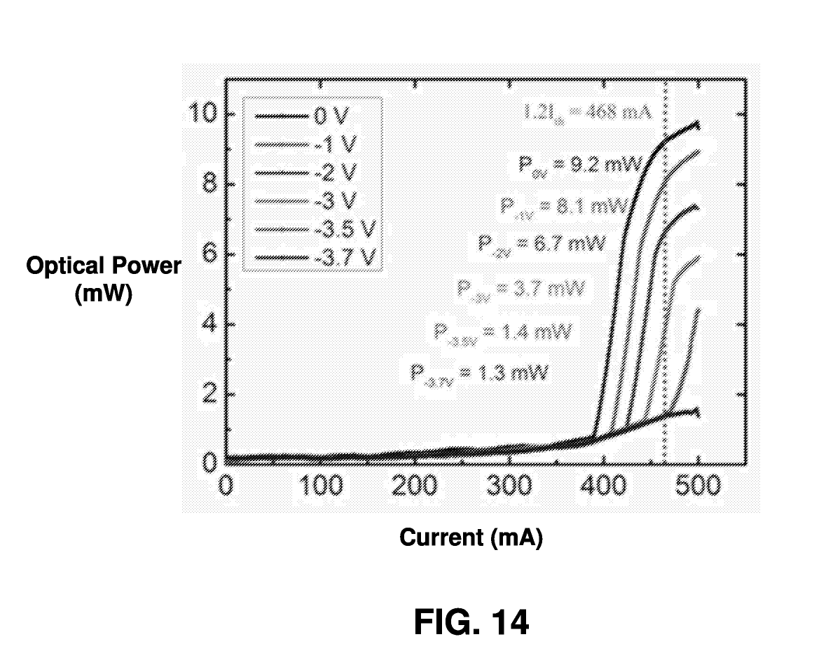

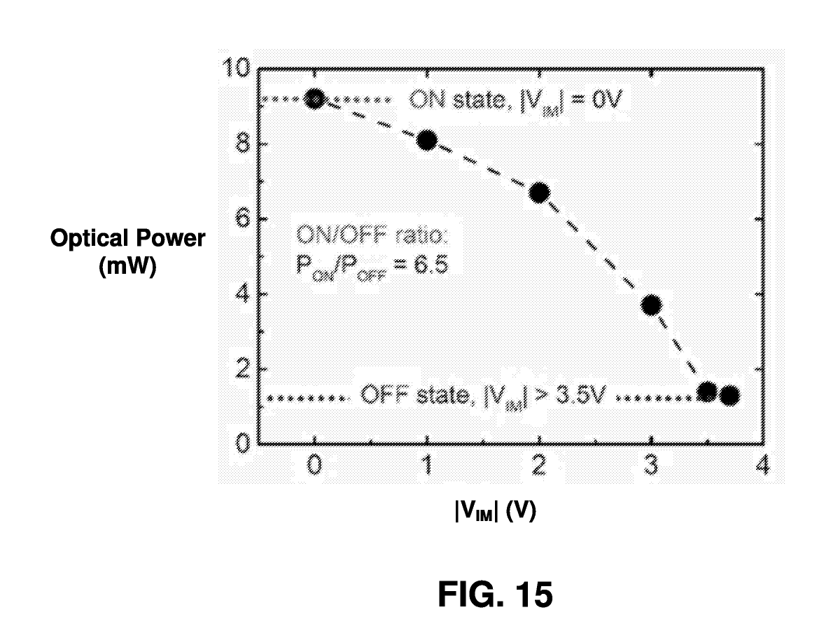

FIG. 14 shows the optical output power vs. the injection current in the gain region (L-I) characteristics for the IML under different bias voltage in the modulator section (V_{IM} from 0 V to −3.7 V). Without any modulation bias (V_{IM}=0 V), the IML shows a threshold current of 390 mA. Further increase in injection current to 468 mA at the gain region (I_{LD}=1.2 Iₜₕ) gave 9.2 mW optical output power under DC operation. The operating current was limited to 500 mA as the thermal roll-over became significant when I_{LD}>500 mA. As expected, a decreasing optical power and increasing lasing threshold current was achieved in the IML device with increasing |V_{IM}|. The optical power of IML at I_{LD}=468 mA was 8.1 mW, 6.7 mW, 3.7 mW, and 1.4 mW at V_{IM}=−1 V, −2V, −3V, and −3.5 V, respectively. The strong V_{IM}-dependence in optical power is evident in FIG. 15, indicating the amplitude modulation effect. When |V_{IM}|>3.5 V, the lasing was suppressed at I_{LD}=468 mA, which representing the Off state. The IML has its maximum emission power at V_{IM}=0V, which is the On state. At I_{LD}=468 mA, the IML exhibited an On/Off ratio (P_{ON}/P_{OFF}) of 6.5 (˜8.1 dB) with a relatively small bias of 0/−3.5V, compared to ˜7 V required in c-plane modulators.

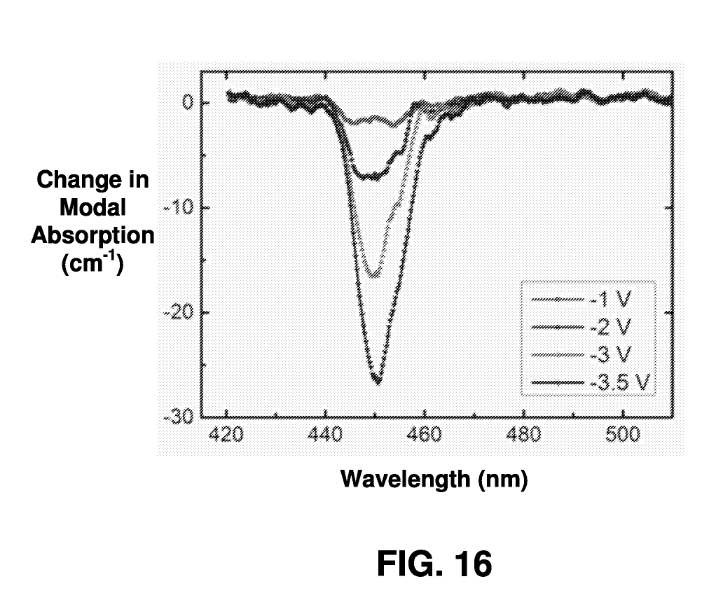

To study the electroabsorption response in semipolar (202̅1̅) InGaN/GaN QWs based integrated modulator, the modal absorption was measured using segmented contact method. FIG. 16 shows the changes in modal absorption with V_{IM} varied from −1 V to −3.5 V, which were calculated by subtracting the measured unbiased absorption spectrum from that of the biased absorption spectrum. The change is due to the applied external field on IM partially cancelling the built-in polarization-induced electric fields in the active region, thereby increasing the absorption with increasing V_{IM}. The measured change in modal absorption at the IM section at V_{IM}=−3.5 V is −27 cm⁻¹, which corresponds to an absorption coefficient change of ˜600 cm⁻¹ at the lasing wavelength. Thus, the significant change in absorption coefficient in IM region in response to modulation bias is effective for modulating the optical output power of IML

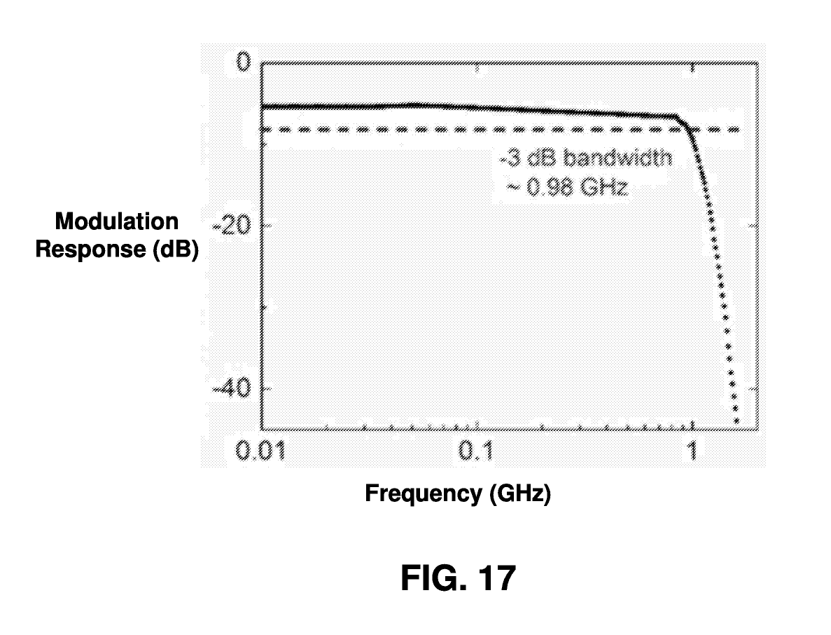

For a proof-of-concept demonstration of AC modulation, the inventors performed a small signal modulation measurement by applying −10 dBm AC signal to the integrated modulator while pumping the gain region with a constant driving current (470 mA). A −3 dB bandwidth of ˜0.98 GHz was measured in the IML with |V_{IM}|=3V (see FIG. 17). The frequency response is limited by the bandwidth of the photodetector, but nevertheless, this demonstration again proves the feasibility of using IML for data transmission.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

1. An apparatus for simultaneous generation of high intensity light and modulated light signals at low modulation bias operating characteristics, the apparatus comprising:
a semipolar or nonpolar GaN-based substrate;
a reverse-biased waveguide modulator section; and
a forward-biased gain section based on InGaN/GaN quantum-well active regions, wherein the forward-biased gain section is grown on the semipolar or nonpolar GaN-based substrate.

2. The apparatus of claim 1, wherein the semipolar or nonpolar GaN-based substrate comprises a bulk GaN substrate or a group-III-nitride-based template-substrate.

3. The apparatus of claim 1, wherein the template substrate includes planar, micro-structured crystals or nano-structured crystals of GaN fabricated on silicon, sapphire, silicon carbide, AlN, or InN substrates.

4. The apparatus of claim 1, further comprising a monitoring photodetector section configured to enable power monitoring and auto-tuning.

5. The apparatus of claim 4, wherein the reverse-biased waveguide modulator section comprises the monitoring photodetector section.

6. The apparatus of claim 1, wherein the reverse-biased waveguide modulator section comprises a forward-biased semiconductor optical amplifier section configured to enable use of high power light sources.

7. (canceled)

8. The apparatus of claim 1, wherein the reverse-biased waveguide modulator section comprises a semiconductor saturable absorber section configured to enable pulse generation or optical clocking.

9. (canceled)

10. The device according to claim 9, wherein the forward-biased gain section comprises a superluminescent diode or light-emitting diodes.

11. The apparatus of claim 1, wherein the apparatus is configured to emit light having a wavelength between 440 and 470 nm.

12. A communication system configured to enable high-rate data transmission, wherein the communication system includes the apparatus of claim 1 as a high-speed and low-power-consumption transmitter.

13. The communication system of claim 12, wherein the communication system is configured to utilize the apparatus to transmit data through free-space, fiber-based channel, or water.

14. An SSL-VLC multiple function lamp for smart lighting, wherein the SSL-VLC multiple function lamp includes the apparatus of claim 1.

15. A method of fabricating a multi-section group-III nitride semiconductor apparatus, the method comprising:
growing an InGaN laser diode epitaxial structure in a semipolar or nonpolar GaN-based substrate.

16. The method of claim 15, wherein the epitaxial structure comprises one or more of an Si-doped n-GaN template, an Si-doped n-InGaN separate confinement heterostructure (SCH), a waveguiding layer, an undoped multiple quantum well (MQW) active region with InGaN quantum wells (QWs) and GaN barriers, a doped p-AlGaN electron blocking layer (EBL), a low Mg-doped p-InGaN SCH waveguiding layer, a standard Mg-doped p-GaN cladding layer, or a highly Mg-doped p-GaN contact layer.

17. The method of claim 15, further comprising:
defining a ridge waveguide multi-section laser diode using ultraviolet (UV) photolithography and inductively coupled plasma (ICP) etching.

18. The method of claim 17, further comprising:
etching, into an InGaN cladding layer, an isolation trench between an IM region and a gain region.

19. The method of claim 18, further comprising:
removing a metal contact layer and a highly doped GaN layer to provide electrical isolation and maintain optical coupling.

20. The method of claim 15, further comprising:
dry-etching facets along an a-direction without dielectric coating.

21. The method of claim 15, further comprising:
depositing Pd/Au and Ti/Al/Ti/Au metallization layers using sputter as p- and n-electrodes, respectively.

22. The method of claim 15, further comprising:
selecting an In concentration and thickness of an InGaN well that enables a production of wavelengths of light in the ultraviolet, visible, or near-infrared regime.
